(19) United States
(12) Patent Application Publication
(10) Pub. No.: US 2025/0151501 A1
(43) Pub. Date: May 8, 2025

(54) LIGHT EMITTING DIODE (LED) FOR OPTICAL EFFICIENCY

(71) Applicant: PURE IMPACT FZCO, Dubai (AE)

(72) Inventor: Huseyin Cenk YABAS, Dubai (AE)

(21) Appl. No.: 18/836,765

(22) PCT Filed: Feb. 9, 2022
(86) PCT No.: PCT/IB2022/051156

§ 371 Date: Aug. 8, 2024

(51) Int. Cl. H10H 29/854; H02S 40/10; H02S 40/30; H10H 29/01; H10H 29/24

(52) U.S. Cl. CPC H10H 29/854; H02S 40/30; H10H 29/0362; H10H 29/24; H02S 40/10

(57) ABSTRACT

There is disclosed a method of manufacturing a light emitting diode (LED) arrangement, the method comprising the steps of installing an LED on a circuit board; and covering the circuit board and other electronic components on the circuit board with a layer of silicon coating; wherein a top emitting area of the LED is kept exposed or uncovered for increasing efficiency of the LED arrangement. Also disclosed is a lighting system, comprising a plurality of light emitting diode (LED) strips in connection with a photo-voltaic (PV) panel, the LED strips comprising a plurality of LEDs and infra-red (IR) LEDs, wherein the plurality of LEDs and IR LEDs are installed on the LED strips at a ratio of 1:8, for mitigating shadow losses and for increasing efficiency of the lighting arrangement.

### FIELD OF THE INVENTION

The present invention relates to the field of farming and plant growth, and more particularly to a light emitting diode (LED) design for optical efficiency when being used in a farming environment.

### BACKGROUND OF THE INVENTION

Background description includes information that may be useful in understanding the present invention. It is not an admission that any of the information provided herein is prior art or relevant to the presently claimed invention, or that any publication specifically or implicitly referenced is prior art.

Traditionally employed lighting devices have numerous disadvantages associated with being used in a farming environment. Bulbs of the grow lights used need to be frequently changed. Thus, their running costs are increased in the long term. They have to be hung higher than other lights to protect the plants and a complex cooling system should be established which will also generate costs. In addition to this, the lights or bulbs used generate a big amount of heat and get extremely hot. Therefore, they are not suitable for smaller spaces, especially if not cooled properly. Another additional cost is the excessive water and nutrient bills due to uncontrolled evaporation.

Further, other lights used have high levels of infrared radiations which can damage plants in the long run. High-pressure sodium (HPS) lamps are a family of high intensity light bulbs, which are commonly used in indoor farming environments. However, these HPS bulbs create much more green and yellow light than the plants actually need, wasting energy. They are also not great for the environment because the bulbs contain toxic metals. Considering the use of fluorescent lights as grow lights, the major downside is the small yield per watt. Fluorescent lights are also not as useful during the vegetative and flowering stages of plant growth because the fluorescent light fails to penetrate deep down into the plant (considering that the light emitted is not strong enough). All other types of lights used tend to be either too expensive or have poor performance issues. The most recently emerging lights used for supporting plant growth are LEDs. However the traditionally employed LED lights tend to result in lower efficiencies in due course and fail to keep up with the required or expected performance levels.

Accordingly, there exists a need for a lighting device, which overcomes drawbacks of traditionally employed lighting techniques and/or systems for farming.

### SUMMARY OF THE INVENTION

Therefore it is an object of the present invention to develop a lighting device or LED design, which overcomes drawbacks of traditionally employed growing techniques and/or systems.

There is disclosed a method of manufacturing a light emitting diode (LED) arrangement, the method comprising the steps of installing an LED on a circuit board; and covering the circuit board and other electronic components on the circuit board with a layer of silicon coating; wherein a top emitting area of the LED is kept exposed or uncovered for increasing efficiency of the LED arrangement.

In an embodiment of the present invention, the LED is a phosphor-silicon chip.

In another embodiment of the present invention, the other electronic components comprise copper and soldered areas of the circuit board.

In an embodiment of the present invention, the LED arrangement is used as a grow light in an indoor farming environment.

In another embodiment of the present invention, the layer of silicon coating protects the circuit board and electronic components on the circuit board from dust and moisture.

In another embodiment of the present invention, the layer of silicon coating is 0.7 mm in thickness.

In another embodiment of the present invention, the LED has dimensions of 3 mm×3 mm×0.7 mm.

In another embodiment of the present invention, the layer of silicon coating is 3D printed over the circuit board and other electronic components on the circuit board.

As another aspect of the present invention, a lighting system is disclosed, comprising a plurality of light emitting diode (LED) strips in connection with a photo-voltaic (PV) panel, the LED strips comprising a plurality of LEDs and infra-red (IR) LEDs, wherein the plurality of LEDs and IR LEDs are installed on the LED strips at a ratio of 1:6 to 1:10 (preferably 1:8), for mitigating shadow losses and for increasing efficiency of the lighting arrangement.

In an embodiment of the present invention, the plurality of LED strips are covered with a layer of silicon coating for protecting the plurality of LED strips from impurities.

In an embodiment of the present invention, a top emitting area of the plurality of LEDs and IR LEDs is kept exposed or uncovered by the layer of silicon coating for increasing efficiency of the plurality of LEDs and IR LEDs.

In an embodiment of the present invention, the lighting system is used as grow lights for an indoor farming environment.

In another embodiment of the present invention, the plurality of LED strips are connected to each other in a series connection.

In another embodiment of the present invention, an input to the plurality of LED strips is voltage which is generated by the PV panel.

In another embodiment of the present invention, the lighting system further comprises robotic brushes for daily cleaning of the PV panel.

### BRIEF DESCRIPTION OF THE DRAWINGS

The subject matter that is regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 shows a perspective view of the LED in accordance with the present invention.

FIG. 2 depicts a top view, side view and a bottom view of the LED in accordance with the present invention.

FIG. 3 shows the LED strip circuit diagram in accordance with the present invention.

FIG. 4A-4C show the manufacturing steps of the LED in accordance with the present invention.

FIG. 5 illustrates an LED strip in accordance with the present invention.

FIG. 6 shows the LED strip in connection with a photo-voltaic (PV) panel, in accordance with the present invention.

### DETAILED DESCRIPTION OF THE INVENTION

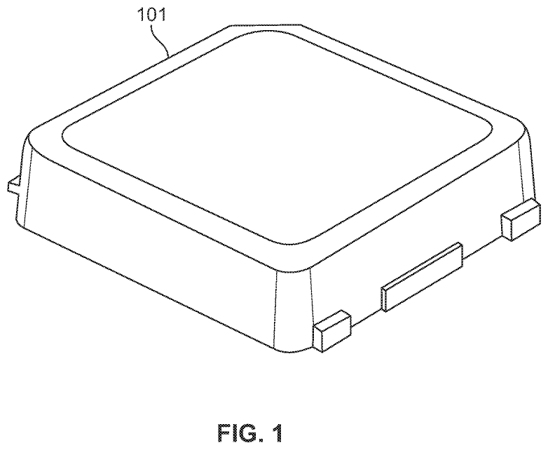

The aspects of the proposed lighting device or LED design for farming applications, according to the present invention will be described in conjunction with FIGS. 1-6. In the Detailed Description, reference is made to the accompanying figures, which form a part hereof, and in which is shown by way of illustration specific embodiments in which the invention may be practiced. It is to be understood that other embodiments may be utilized and logical changes may be made without departing from the scope of the present invention. The following detailed description, therefore, is not to be taken in a limiting sense, and the scope of the present invention is defined by the appended claims.

An objective of the present invention is to propose a light emitting diode (LED) design for use as grow lights in a hydroponic farming arrangement with an aim to achieve maximum optical and electrical efficiency.

LEDs have many advantages over alternative light sources, including lower power consumption, longer lifetime, improved physical robustness and smaller size. LED lights (grow lights) are necessary to be installed in rooms which hold growing plants. Factors to be kept in mind when growing plants in an indoor environment include the temperature of the indoor room (room temperature is adequate in most cases), and humidity levels, which should stay within a certain level for optimal plant growth. Accordingly, using the best lighting as grow lights for the growing plants is crucial along with having the requisite spectrum of light that the growing plants (such as vegetable crops, leafy crops or flowers and houseplants) need. Light emitting diode (LED) lights-if efficient enough, are a recommended option for promoting optimal plant growth (by producing the type of light needed by plants).

LED lights are used in the grow room (of a vertical farming system) to create the perfect environment to grow vegetables at a large scale with shorter growing cycles and higher yields. LEDs generate far less heat than all other types of grow lights. As a result, less ventilation is needed to prevent excess moisture, pest problems, and other ventilation related issues. However LED fixtures used in traditional farming system end up having shorter lifespans as they are affected by the indoor controlled environment. Drawbacks face by traditional lighting systems used for farming purposes include the lighting fixtures used in traditional farming system having shorter lifespans as they are affected by the indoor controlled environment, and thereby leading to increased maintenance costs. Accordingly, an objective of the present invention is to propose an LED design for increasing electrical and optical efficiency (95% efficiency) when being used as grow lights in an indoor farming/vertical farming technique.

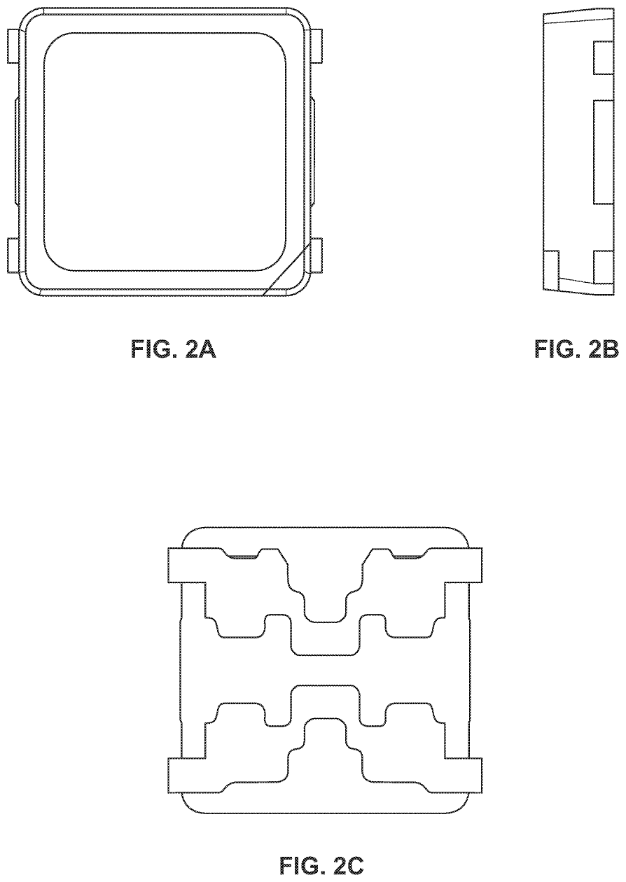

FIG. 1 shows a perspective view of the LED in accordance with the present invention, and FIG. 2 depicts a top view, side view and a bottom view of the LED in accordance with the present invention.

In a primary embodiment of the present invention, an upper portion or top portion 109 of the LED 101 is kept open or exposed, whereas the remaining area of the LED is covered. The said covering is done via 3D printing a silicone layer 107 around the LED 101 without covering or touching the top portion 109, and thereby enabling higher optical efficiency. The benefits of using high efficient LED fixtures in indoor farming/vertical farming techniques include creating the perfect environment to grow vegetables at a large scale with shorter growing cycles and higher yields. The present invention deals with a new LED design by exposing only an upper portion or top portion 109 of the LED 101, whereas the remaining area of the LED is covered—to keep the LED waterproof and dustproof, without using any additional glass or plastic covers, or in other words—LED fixtures with water and dustproof properties without using any glass or plastic cover. The proposed LED includes highly reflective surfaces.

LED lights are made up of a number of diodes, and each diode is created from a particular semiconductor material. One of the layers of the used semiconductor material will have an excess of electrons, whereas one layer will be depleted of electrons. This difference in the electron levels leads to the existing electrons to move from one layer to the other, thereby creating light through the electronic excitation which occurs owing to the said movement of electrons (from one layer to the next). In traditional manufacturing methods, the diodes of the LED are covered with a transparent glass or plastic covering. The covering of an LED source regulates the amount of light that is transmitted or diffused, and it is preferred to use a material, which allows for maximum clarity and one, which allows for maximum optical efficiency (optimum light transmission). Once all of the required electronic components have been installed on the integrated circuit (IC), traditionally implemented methods involve depositing a silicon layer directly onto the IC substrate from solution to result in silicon-based microelectronic devices. These methods involve heating purified silicon in a vacuum and allowing the resulting spray (or mist) of silicon atoms to coat the IC substrate surface, acting exactly how a layer of plastic would for protection of the IC substrate and the components present on the substrate. However, studies have clearly shown how the sprayed silicon mist (although a thin film) leads to an overall 5-10% loss in optical efficiency.

A method of manufacturing the proposed LED 101 in accordance with the present invention involves 3D printing a layer of silicon 107 over the IC 103 on which the proposed LED is installed, covering all exposed portions on the whole IC board 103 (including the copper and soldered areas 105), however leaving out a top portion or area 109 of the LED 101. The top emitting area 109 of the LED is left exposed and uncovered (by silicon or any other material based coverings). In an embodiment of the present invention, the layer of silicon 107 being 3D printed on the IC substrate 103 is 0.7 mm in thickness. A phosphor-silicon chip is used for the LED (phosphor being a luminescent material, absorbs light at the blue wavelength and reemits photons at longer wavelengths).

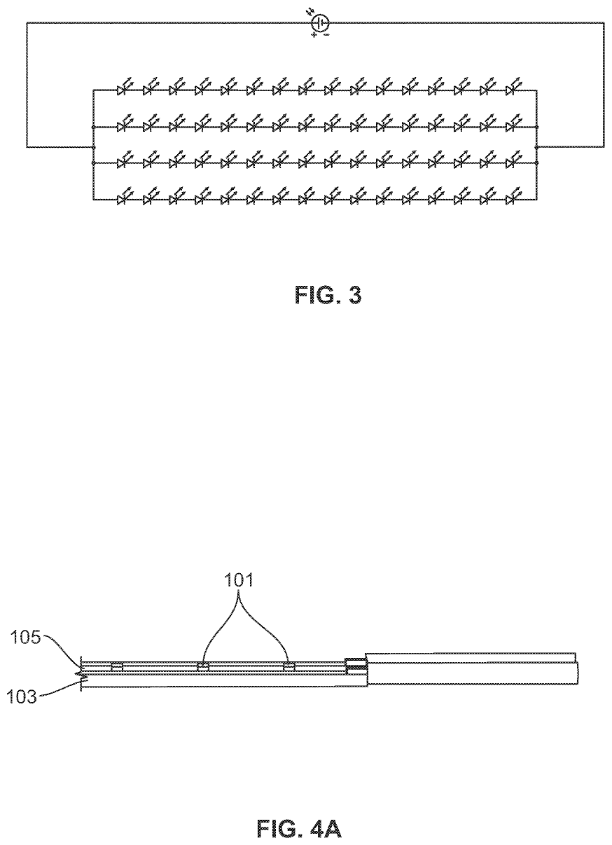

The LED strip circuit diagram in accordance with the present invention is shown in FIG. 3. Experimental analysis conducted on the manufactured LED 101 with an exposed upper portion 109 show that the proposed LED design possesses maximum electrical and optical efficiency (in comparison with traditionally implemented LED designs). The method of manufacture involves using a 3D printer nozzle for printing a layer of silicon onto the circuit board, and leaving out a top emitting area of the LED while printing. An extrusion pressure of 0.4-0.6 MPa (please confirm/amend) is used for the printing, for adjusting the pressure of the requisite air supply for conducting the printing. Please provide further details as an example mentioning the pressure range used for printing the silicon layer, nozzle specifications and a temperature range used for the printing.

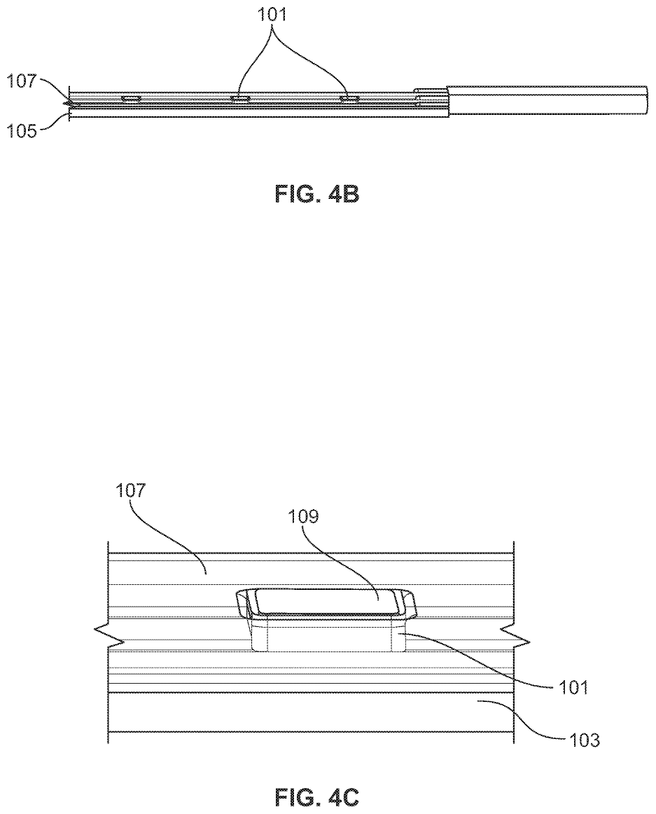

FIG. 4A-4C show the manufacturing steps of the LED in accordance with the present invention. FIG. 4A depicts a plurality of LEDs 101 on a circuit board 103 with required copper and soldered components 105. FIG. 4B depicts the subsequent step of the silicon layer 107 3D printed on the circuit board 103, however leaving a top portion 109 of the LED 101 exposed. FIG. 4C clearly shows the exposed or uncovered top emitting area 109 of the LED 101, whose remaining parts are covered with a silicon coating 107. The advantage of leaving out the upper portion 109 of the LED while 3D printing the silicon layer 107 over the IC board 103 (for protection against dust, moisture and other external factors or impurities), is to maximize the optical efficiency of the LEDs being used. By printing silicon 107 over the remaining parts of the board as well as around the LED 101, all these covered areas will remain protected from foreign substance, in addition to dust and moisture, which can deteriorate the overall working of the LED 101 in due course (and result in reduces optical efficiency). However, by keeping only the top emitting area 109 of the LED component exposed (or uncovered), there remains no obstruction for the emitted light to pass through, and thereby ensures maximum efficiency. In an embodiment of the present invention, the LED 101 in accordance with the present invention has dimensions of 3 mm×3 mm×0.7 mm. The diodes used are thin. In another embodiment the silicon layer 107 is 2.5D printed on the circuit board 103—considering that the actual geometry generation is only in the x and y axes.

Please clarify whether a layer of paint—polished high purity aluminum or BaSO4 filled paint—is required in accordance with the present invention.

For various applications of an LED, the requirement varies, and the LEDs installed or used are evaluated to find a suitable color and emmission property based on the application (for example, indoor farming). Accordingly, altering the proportions of silicon and phosphor used in the LED helps to control color of the emitted light as well as to control an angle of the light emission. Please provide the spectrum range/best optical spectrum for indoor farming.

The below table shows experimental results showing a high optical performance and efficiency of the implemented LEDs in accordance with the present invention. Please send us the below table in word format, or with better clarity.

| | | | | | | | |
|---|---|---|---|---|---|---|---|
| [symbol] | | | | [symbol] | | | |
| [symbol] | | | [symbol] | [symbol] | | | [symbol] |
| [symbol] | | | | [symbol] | | | |
| CCT | | | [symbol] | CCT | | | [symbol] |
| [symbol] | | | [symbol] | [symbol] | | | [symbol] |
| [symbol] | | | [symbol] | [symbol] | | | [symbol] |
| [symbol] | | | [symbol] | [symbol] | | | [symbol] |
| [symbol] | | | [symbol] | [symbol] | | | [symbol] |
| [symbol] | | | [symbol] | [symbol] | | | [symbol] |
| [symbol] | | | [symbol] ° C. | [symbol] | | | [symbol] ° C. |
| [symbol] | | | [symbol] ° C. | [symbol] | | | [symbol] ° C. |
| [symbol] | [symbol] | [symbol] | [symbol] | [symbol] | [symbol] | [symbol] | [symbol] |
| [symbol] | [symbol] ° C. | [symbol] ° C. | [symbol] ° C. | [symbol] | [symbol] ° C. | [symbol] ° C. | [symbol] ° C. |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | 100% | 100% | 100% | [symbol] | 100% | 100% | 100% |
| [symbol] | 100% | 100% | 100% | [symbol] | 100% | 100% | 100% |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] |

[symbol]

indicates data missing or illegible when filed

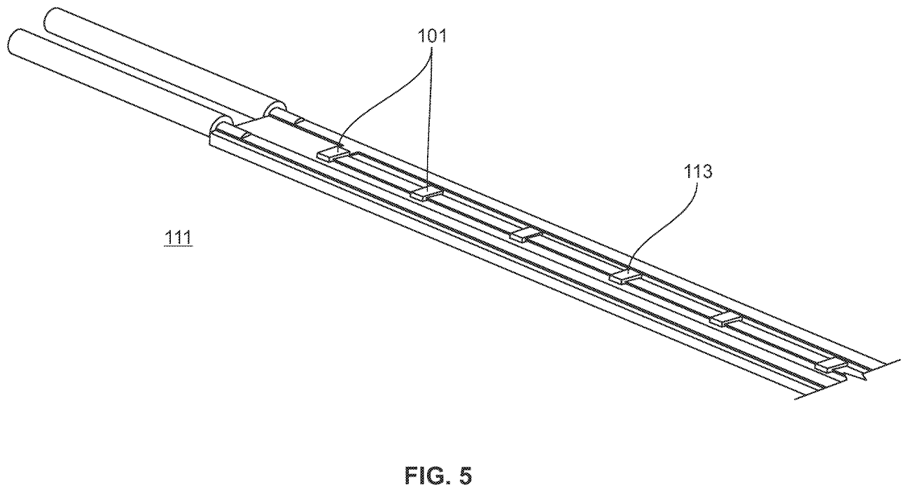

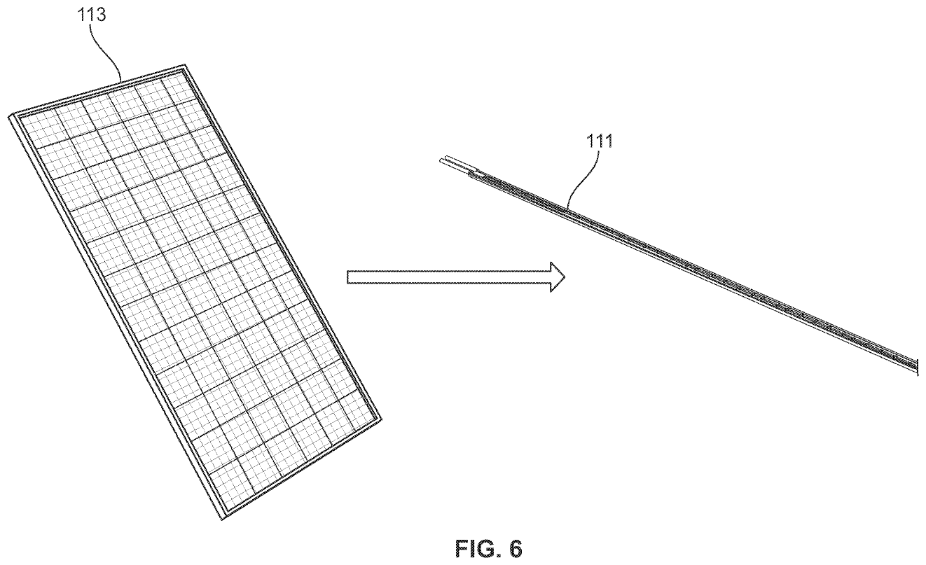

In another embodiment of the present invention, a lighting system is proposed for indoor farming applications, comprising a plurality of LED strips 111 as grow lights, the LED strips 111 comprising a number of LEDs 101 mixed with infra-red (IR) LEDs 113 (device that emits light in the infrared range of the electromagnetic radiation spectrum), at a ratio of 1:8 (one IR LED 113 between 8 normal LEDs 101). The voltage drop of IR LEDs affect overall functionality, efficiency and life cycle of the LED strips being used. Also, the used IR LEDs 113 are shadow tolerant and result in 30% more harvest in comparison to not using IR LEDs in between the normal LEDs of the LED strips. FIG. 5 illustrates an LED strip 111 in accordance with the present invention. In another embodiment and as shown in FIG. 6, an LED strip 111 includes 64 individual LEDs and photo-voltaic (PV) panels 115 are connected with the said LED strips. As a result of this connection input to the LED strips 111 is voltage (generated from solar energy), and an output of the LED strips is photons (in the form of emitted light). In contrast, an input to the PV panels 115 is photons (light from the sun), and an output of the PV panels is voltage (approximately 40V). Therefore, as seen, an output of one section of the system is used as input to the next section of the system and vice-versa, thereby minimizing waste and/or losses and maximizing utilization and overall efficiency of the proposed system.

In another embodiment of the present invention, electrical output of the proposed system may be impedance matched by adjusting or altering the number of LEDs 101 used in the LED strips 111—and by avoiding use of any additional electronic or electrical components such as transformers for the same. In addition, the plurality of LED strips 111 are connected in series connection, for increasing the voltage of the PV panels 115. Another step taken to increase overall efficiency and output of each of the components used in the system includes employing dry robotic brushes for daily cleaning the solar panels (removing accumulated dust and/or other foreign particles or impurities). Further, each of the PV panels 115 used are kept at a minimum distance of 2 meters apart from each other to minimize voltage sparks during operation.

Many changes, modifications, variations and other uses and applications of the subject invention will become apparent to those skilled in the art after considering this specification and the accompanying drawings, which disclose the preferred embodiments thereof. All such changes, modifications, variations and other uses and applications, which do not depart from the spirit and scope of the invention, are deemed to be covered by the invention, which is to be limited only by the claims, which follow.

1. A method of manufacturing a light emitting diode (LED) arrangement, the method comprising the steps of:
installing an LED on a circuit board; and
covering the circuit board and other electronic components on the circuit board with a layer of silicon coating; wherein a top emitting area of the LED is kept exposed or uncovered for increasing efficiency of the LED arrangement.

2. The method of claim 1, wherein the LED is a phosphor-silicon chip.

3. The method of claim 1, wherein the other electronic components comprise copper and soldered areas of the circuit board.

4. The method of claim 1, wherein the LED arrangement is used as a grow light in an indoor farming environment.

5. The method of claim 1, wherein the layer of silicon coating protects the circuit board and electronic components on the circuit board from dust and moisture.

6. The method of claim 1, wherein the layer of silicon coating is 0.7 mm in thickness.

7. The method of claim 1, wherein the LED has dimensions of 3 mm×3 mm×0.7 mm.

8. The method of claim 1, wherein the layer of silicon coating is 3D printed over the circuit board and other electronic components on the circuit board.

9. A lighting system, comprising:
a plurality of light emitting diode (LED) strips in connection with a photo-voltaic (PV) panel, the LED strips comprising a plurality of LEDs and infra-red (IR) LEDs,
wherein the plurality of LEDs and IR LEDs are installed on the LED strips at a ratio of 1:6 to 1:10, for mitigating shadow losses and for increasing efficiency of the lighting arrangement.

10. The lighting system of claim 9, wherein the plurality of LEDs and IR LEDs are installed on the LED strips at a ratio of 1:8.

11. The lighting system of claim 9, wherein the plurality of LED strips are covered with a layer of silicon coating for protecting the plurality of LED strips from impurities and a top emitting area of the plurality of LEDs and IR LEDs is kept uncovered by the layer of silicon coating for increasing efficiency of the plurality of LEDs and IR LEDs.

12. The lighting system of claim 9, wherein the lighting system is used as grow lights for an indoor farming environment.

13. The lighting system of claim 9, wherein the plurality of LED strips are connected to each other in a series connection.

14. The lighting system of claim 9, wherein an input voltage to the plurality of LED strips is generated by the PV panel.

15. The lighting system of claim 9, further comprising robotic brushes adapted for cleaning of the PV panel.
